(19) United States
(12) Patent Application Publication
(10) Pub. No.: US 2025/0167009 A1
(43) Pub. Date: May 22, 2025

(54) SUBSTRATE PROCESSING APPARATUS AND SUBSTRATE PROCESSING METHOD

(71) Applicant: Tokyo Electron Limited, Tokyo (JP)

(72) Inventors: Kazuya TAKAHASHI, Nirasaki City (JP); Kuniyasu SAKASHITA, Oshu City (JP); Atsushi ENDO, Nirasaki City (JP); Junya KOJIMA, Nirasaki City (JP)

(73) Assignee: Tokyo Electron Limited, Tokyo (JP)

(21) Appl. No.: 19/034,742

(22) Filed: Jan. 23, 2025

Related U.S. Application Data
(63) Continuation of application No. PCT/JP2023/026053, filed on Jul. 14, 2023.

(30) Foreign Application Priority Data
Jul. 28, 2022 (JP) 2022-120776

(51) Int. Cl. H01L 21/67; C23C 16/455

(52) U.S. Cl. CPC H01L 21/67017; C23C 16/45519; C23C 16/45561

(57) ABSTRACT

A substrate processing apparatus includes: a processing container that accommodates a plurality of substrates arranged in multiple tiers; a processing gas supply pipe that extends along an arrangement direction of the plurality of substrates and supplies a processing gas into the processing container; and a pair of inert gas supply pipes that is provided at positions sandwiching the processing gas supply pipe therebetween along a circumferential direction of the plurality of substrates while extending along the arrangement direction, and supply an inert gas into the processing container. The pair of inert gas supply pipes are configured to inject the inert gas toward an inner surface of a sidewall of the processing container, so that the inner surface forms a flow of the inert gas in the circumferential direction of the plurality of substrates.

### CROSS-REFERENCE TO RELATED APPLICATIONS

This application is a continuation application of International Patent Application No. PCT/JP2023/026053, filed on Jul. 14, 2023, which claims priority from Japanese Patent Application No. 2022-120776, filed on Jul. 28, 2022, with the Japan Patent Office, all of which are incorporated herein in their entireties by reference.

### TECHNICAL FIELD

The present disclosure relates to a substrate processing apparatus and a substrate processing method.

### BACKGROUND

In a vertical heat treatment apparatus, a technique is known in which a pair of inert gas supply nozzles are arranged to sandwich a processing gas supply nozzle along the circumferential direction of a substrate (see, e.g., Japanese Patent Laid-Open Publication No. 2009-206489).

### SUMMARY

A substrate processing apparatus according to an aspect of the present disclosure includes: a processing container that accommodates a plurality of substrates arranged in multiple tiers; a processing gas supply pipe that extends along an arrangement direction of the plurality of substrates and supplies a processing gas into the processing container; and a pair of inert gas supply pipes that is provided at positions sandwiching the processing gas supply pipe therebetween along a circumferential direction of the plurality of substrates while extending along the arrangement direction, and supply an inert gas into the processing container. The pair of inert gas supply pipes are configured to inject the inert gas toward an inner surface of a sidewall of the processing container.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a longitudinal cross-sectional view illustrating a substrate processing apparatus according to a first embodiment.

FIG. 2 is a transverse cross-sectional view illustrating the substrate processing apparatus according to the first embodiment.

FIG. 3 is a diagram illustrating the direction of gas holes.

FIG. 4 is a diagram illustrating a gas flow in a horizontal direction.

FIG. 5 is a diagram illustrating a gas flow in a horizontal direction.

FIG. 6 is a diagram illustrating a gas flow in a horizontal direction.

FIG. 7 is a diagram illustrating a gas flow in a vertical direction.

FIG. 8 is a transverse cross-sectional view illustrating a substrate processing apparatus according to a second embodiment.

FIG. 9 is a diagram illustrating the direction of gas holes.

FIG. 10 is a diagram illustrating the direction of gas holes.

FIG. 11 is a diagram illustrating the direction of gas holes.

FIG. 12 is a diagram illustrating the direction of gas holes.

### DETAILED DESCRIPTION

In the following detailed description, reference is made to the accompanying drawing, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, non-limiting embodiments of the present disclosure will be described with reference to the accompanying drawings. In all of the drawings, the same or corresponding members or components are denoted by the same or corresponding reference numerals, and overlapping descriptions thereof are omitted.

### First Embodiment

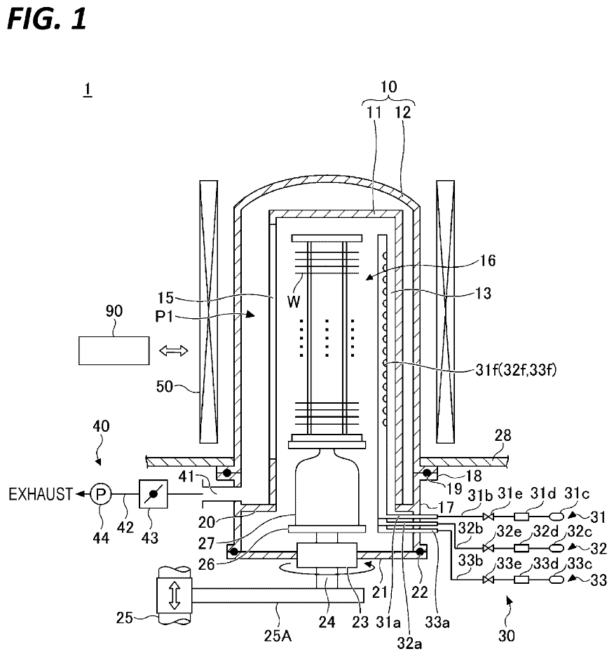

A substrate processing apparatus 1 according to a first embodiment will be described with reference to FIGS. 1 to 7. As illustrated in FIG. 1, the substrate processing apparatus 1 is a batch-type apparatus that processes a plurality of (e.g., 5 to 100) substrates W at once. The substrates W may be, for example, semiconductor wafers.

The substrate processing apparatus 1 includes a processing container 10, a gas supply unit 30, an exhaust unit 40, a heating unit 50, and a control unit 90.

The processing container 10 is internally depressurizable. The processing container 10 accommodates a plurality of substrates W arranged in multiple tiers along the vertical direction. The processing container 10 includes an inner pipe 11 and an outer pipe 12. The inner pipe 11 has a cylindrical shape with an open lower end and a ceiling. The outer pipe 12 has a cylindrical shape with an open lower end and a ceiling that covers the outside of the inner pipe 11. The inner pipe 11 and the outer pipe 12 have a coaxially arranged double pipe structure. The inner pipe 11 and the outer pipe 12 are formed of, for example, quartz.

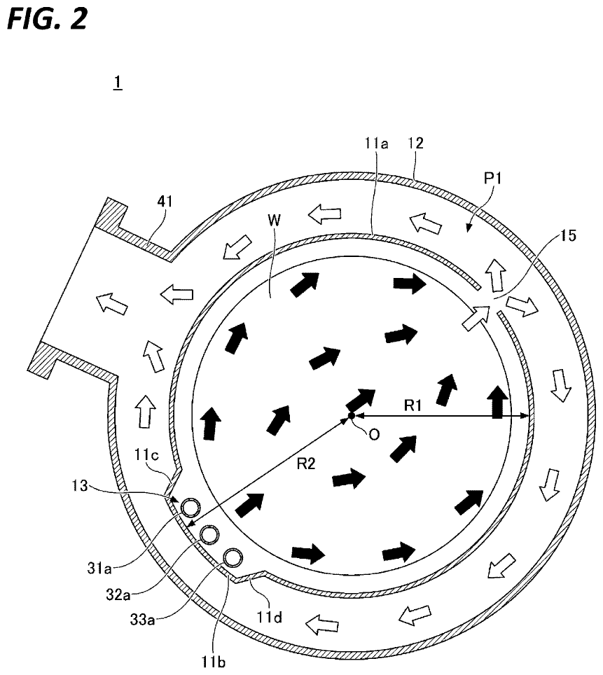

As illustrated in FIG. 2, the inner pipe 11 has a first sidewall 11a, a second sidewall 11b, a third sidewall 11c, and a fourth sidewall 11d. The first sidewall 11a, the second sidewall 11b, the third sidewall 11c, and the fourth sidewall 11d are formed, for example, as an integral body.

The first sidewall 11a extends along the circumferential direction of the substrates W. The first sidewall 11a has an arc shape in a horizontal cross section that is a cross section perpendicular to the arrangement direction of the substrates W. A rectangular exhaust slit 15 is formed along a longitudinal direction (vertical direction) of the first sidewall 11a in a portion of the circumferential direction. A gas in the inner pipe 11 is exhausted through the exhaust slit 15 to a space P1 between the inner pipe 11 and the outer pipe 12. The exhaust slit 15 has a vertical length equal to the vertical length of a boat 16, or is formed so as to extend vertically longer than the vertical length of the boat 16.

The second sidewall 11b is located on a radial outward side of the substrate W from the first sidewall 11a and extends along the circumferential direction of the substrate W. The second sidewall 11b is provided at a position different from the first sidewall 11a in the circumferential direction of the substrate W. The second sidewall 11b has an arc shape in a horizontal cross section. In the horizontal cross section, a radius R2 of the arc of the second sidewall 11b is larger than a radius R1 of the arc of the first sidewall 11a. The difference in length between the radius R2 and the radius R1 is, for example, larger than the diameter of each gas supply pipe (a first inert gas supply pipe 31a, a processing gas supply pipe 32a, and a second inert gas supply pipe 33a) (to be described later). In this case, each gas supply pipe may be accommodated in a nozzle accommodating section 13 (to be described later). Therefore, since it is not necessary to provide a gas supply pipe between the first sidewall 11a and the substrate W, the gap between the inner surface of the first sidewall 11a and the outer end of the substrate W may be narrowed. As a result, it is possible to suppress the film thickness from becoming thicker at the peripheral portion of the substrate W. Also, since the volume inside the inner pipe 11 is reduced, the amount of the gas consumed may be reduced. The circumferential length of the second sidewall 11b is, for example, shorter than the circumferential length of the first sidewall 11a. The circumferential length of the second sidewall 11b is determined, for example, according to the number of gas supply pipes accommodated in the nozzle accommodating portion 13. The second sidewall 11b is provided at a position facing the exhaust slit 15 across the center O of the inner pipe 11 (substrate W).

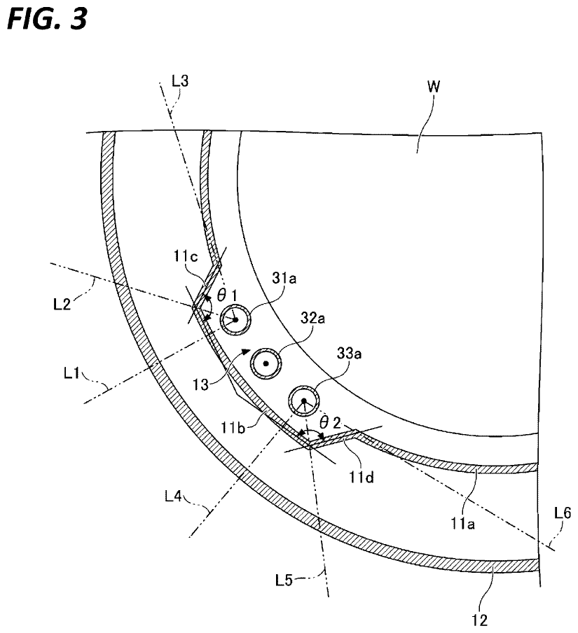

The third sidewall 11c connects one end of the first sidewall 11a and one end of the second sidewall 11b. The third sidewall 11c is continuous with one end of the first sidewall 11a and one end of the second sidewall 11b. As illustrated in FIG. 3, an angle θ1 between the second sidewall 11b and the third sidewall 11c may be, for example, an obtuse angle. In this case, the inert gas injected from a first inert gas supply pipe 31a (to be described later) is likely to form a flow along the inner surface of the first sidewall 11a (e.g., a flow along the circumferential direction of the substrate W). The angle θ1 may be, for example, 100 degrees or more and 150 degrees or less. In this case, the third sidewall 11c may function as a rectifying plate in the circumferential direction of the substrate W. As a result, the inert gas injected from the first inert gas supply pipe 31a (to be described later) may be efficiently introduced in the circumferential direction of the substrate W, thereby reducing the amount of inert gas used in a predetermined process.

The angle θ1 may be, for example, 120 degrees or more and 130 degrees or less. In this case, the third sidewall 11c may further improve the rectifying effect in the circumferential direction of the substrate W.

The fourth sidewall 11d connects the other end of the first sidewall 11a and the other end of the second sidewall 11b. The fourth sidewall 11d is continuous with the other end of the first sidewall 11a and the other end of the second sidewall 11b. As illustrated in FIG. 3, an angle θ2 between the second sidewall 11b and the fourth sidewall 11d may be, for example, an obtuse angle. In this case, the inert gas injected from a second inert gas supply pipe 33a (to be described later) is likely to form a flow along the inner surface of the first sidewall 11a (e.g., a flow along the circumferential direction of the substrate W). The angle θ2 may be, for example, 100 degrees or more and 150 degrees or less. In this case, the fourth sidewall 11d may function as a rectifying plate in the circumferential direction of the substrate W. As a result, the inert gas injected from the second inert gas supply pipe 33a (to be described later) may be efficiently introduced in the circumferential direction of the substrate W, thereby reducing the amount of inert gas used in a predetermined process.

The angle θ2 may be, for example, 120 degrees or more and 130 degrees or less. In this case, the fourth sidewall 11d may further improve the rectifying effect in the circumferential direction of the substrate W.

The second sidewall 11b, the third sidewall 11c and the fourth sidewall 11d protrude outward from the first sidewall 11a in the radial direction of the substrate W, thereby forming a nozzle accommodating portion 13 that accommodates each gas supply pipe.

The lower end of the processing container 10 is supported by a cylindrical manifold 17. The manifold 17 is made of, for example, stainless steel. A flange 18 is formed at the upper end of the manifold 17. The flange 18 supports the lower end of the outer pipe 12. A sealing member 19 such as an O-ring is provided between the flange 18 and the outer pipe 12. Thus, the inside of the outer pipe 12 is kept airtight.

An annular support unit 20 is provided on the inner wall of the upper portion of the manifold 17. The support unit 20 supports the lower end of the inner pipe 11. A lid 21 is air-tightly attached to the opening at the lower end of the manifold 17 via a seal member 22 such as an O-ring. Thus, the opening at the lower end of the processing container 10, i.e., the opening of the manifold 17, is air-tightly closed. The lid 21 is made of, for example, stainless steel.

A rotation shaft 24 is provided through the center of the lid 21 via a magnetic fluid seal 23. The lower portion of the rotation shaft 24 is rotatably supported by an arm 25A of a lifting mechanism 25 including a boat elevator.

A rotation plate 26 is provided at the upper end of the rotation shaft 24. A boat 16, which holds the substrates W, is placed on the rotation plate 26 via a quartz heat retention stand 27. The boat 16 is rotated by rotating the rotation shaft 24. The boat 16 moves up and down integrally with the lid 21 by raising and lowering the lifting mechanism 25. Thus, the boat 16 is inserted into and removed from the processing container 10. The boat 16 may be accommodated in the processing container 10. The boat 16 holds a plurality of substrates W substantially horizontally with intervals in the vertical direction.

The gas supply unit 30 includes a first inert gas supply unit 31, a processing gas supply unit 32, and a second inert gas supply unit 33.

The first inert gas supply unit 31 includes a first inert gas supply pipe 31a in the processing container 10 and a first inert gas supply path 31b outside the processing container 10. The first inert gas supply path 31b is provided with a first inert gas source 31c, a mass flow controller 31d, and a valve 31e in this order from the upstream side to the downstream side in the gas flow direction. As a result, the supply timing of the inert gas from the first inert gas source 31c is controlled by the valve 31e, and the flow rate of the inert gas is adjusted to a predetermined value by the mass flow controller 31d. The inert gas flows from the first inert gas supply path 31b into the first inert gas supply pipe 31a and is injected from the first inert gas supply pipe 31a into the processing container 10. The inert gas is, for example, nitrogen (N₂) gas. The inert gas may be, for example, argon (Ar) gas.

The processing gas supply unit 32 includes a processing gas supply pipe 32a in the processing container 10 and a processing gas supply path 32b outside the processing container 10. The processing gas supply path 32b is provided with a processing gas source 32c, a mass flow controller 32d, and a valve 32e in this order from the upstream side to the downstream side in the gas flow direction. As a result, the supply timing of the inert gas from the processing gas source 32c is controlled by the valve 32e, and the flow rate of the processing gas is adjusted to a predetermined value by the mass flow controller 32d. The processing gas flows from the processing gas supply path 31b into the processing gas supply pipe 32a and is injected from the processing gas supply pipe 32a into the processing container 10. The processing gas is, for example, a silicon source gas. The processing gas may be, for example, a metal source gas. The processing gas may be, for example, an oxidation gas or a nitriding gas.

The second inert gas supply unit 33 includes a second inert gas supply pipe 33a in the processing container 10 and a second inert gas supply path 33b outside the processing container 10. The second inert gas supply path 31b is provided with a second inert gas source 33c, a mass flow controller 33d, and a valve 33e in this order from the upstream side to the downstream side in the gas flow direction. As a result, the supply timing of the inert gas from the second inert gas source 33c is controlled by the valve 33e, and the flow rate of the inert gas is adjusted to a predetermined value by the mass flow controller 33d. The inert gas flows from the second inert gas supply path 33b into the second inert gas supply pipe 33a and is injected from the second inert gas supply pipe 33a into the processing container 10. The inert gas may be, for example, the same as the inert gas in the first inert gas source 31c.

Each gas supply pipe (first inert gas supply pipe 31a, processing gas supply pipe 32a, and second inert gas supply pipe 33a) is fixed to the manifold 17. Each gas supply pipe is made of, for example, quartz. Each gas supply pipe is an L-shaped gas supply pipe that extends linearly in the vertical direction near the second sidewall 11b in the nozzle accommodating portion 13, then, bends in an L-shape within the manifold 17, and extends horizontally to penetrate the manifold 17. Each gas supply pipe is provided side by side at intervals along the circumferential direction of the substrate W, and is formed at the same height as each other.

The first inert gas supply pipe 31a, the processing gas supply pipe 32a, and the second inert gas supply pipe 33a are provided in this order from near the exhaust port 41 along the circumferential direction of the substrate W. A pair of inert gas supply pipes (the first inert gas supply pipe 31a and the second inert gas supply pipe 33a) are provided at positions sandwiching the processing gas supply pipe 32a along the circumferential direction of the substrate W. The first inert gas supply pipe 31a and the second inert gas supply pipe 33a are configured to inject the inert gas toward the inner surface of the second sidewall 11b, the third sidewall 11c, or the fourth sidewall 11d. In this case, the inert gas bounces off the inner surface of the second sidewall 11b, the third sidewall 11c, or the fourth sidewall 11d, so that the inert gas is efficiently supplied to the gap between the outer end of the substrate W and the inner surface of the first sidewall 11a. Therefore, the pressure in the gap between the outer edge of the substrate W and the inner surface of the first sidewall 11a may be made relatively high by using a small flow rate of the inert gas, so that the processing gas may be suppressed from flowing into the gap. As a result, the amount of inert gas used may be reduced, thereby reducing the environmental load, while promoting the supply of the processing gas to the center of each substrate W and reducing the difference in the amount of processing gas supplied between the peripheral portion and the center portion of each substrate W. As a result, the in-plane uniformity of the processing is improved.

For example, the first inert gas supply pipe 31a injects the inert gas such that the inert gas is supplied into the inner pipe 11 along the inner surface of the third sidewall 11c. For example, the second inert gas supply pipe 33a injects the inert gas such that the inert gas is supplied into the inner pipe 11 along the inner surface of the fourth sidewall 11d. The processing gas supply pipe 32a is configured to inject the processing gas, for example, toward the inner surface of the second sidewall 11b. The processing gas supply pipe 32a may be configured to inject the processing gas, for example, directly toward the center O of the substrate W without injecting the processing gas toward the second sidewall 11b.

A plurality of gas holes 31f (first gas holes) is provided in the first inert gas supply pipe 31a at a portion located in the inner pipe 11. A plurality of gas holes 32f is provided in the processing gas supply pipe 32a at a portion located in the inner pipe 11. A plurality of gas holes 33f (second gas holes) is provided in the second inert gas supply pipe 33a at a portion located in the inner pipe 11. The gas holes (gas holes 31f, gas holes 32f, and gas holes 33f) are provided at predetermined intervals along the extension direction of each gas supply pipe. Each gas hole injects gas in the horizontal direction. The interval between the gas holes is set to be the same as, for example, the interval between the substrates W held in the boat 16. The height position of each gas hole is set to be the same as, for example, that of each substrate W.

As illustrated in FIG. 3, a half line extending from the center of the first inert gas supply pipe 31a toward the radial outward side of the substrate W is defined as a half line L1. A half line extending from the center of the first inert gas supply pipe 31a toward the boundary between the second sidewall 11b and the third sidewall 11c is defined as a half line L2. A half line extending from the center of the first inert gas supply pipe 31a toward the boundary between the first sidewall 11a and the third sidewall 11c is defined as a half line L3.

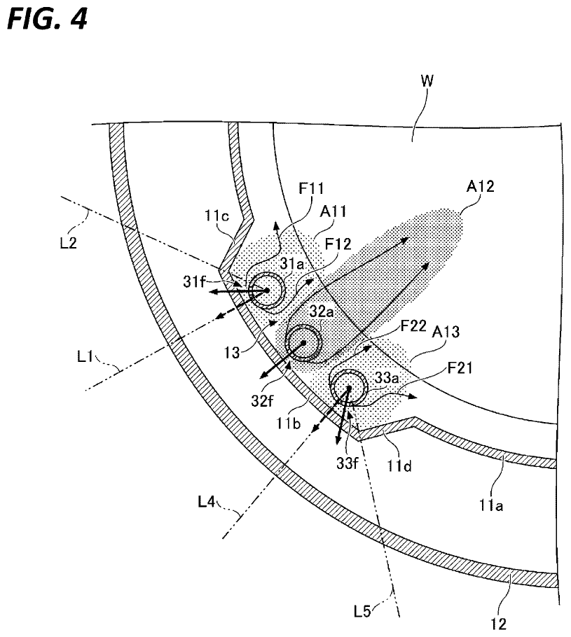

As illustrated in FIG. 4, each gas hole 31f may be located on the side of the second sidewall 11b (opposite to the side of the substrate W) between the half line L1 and the half line L2 in the pipe wall of the first inert gas supply pipe 31a (first pipe wall). That is, each gas hole 31f may be located in an area between the half line L1 and the half line L2 in the pipe wall of the first inert gas supply pipe 31a (first pipe wall). Thus, the first inert gas supply pipe 31a may inject inert gas toward the area between the half line L1 and the half line L2 of the second sidewall 11b (e.g., solid line arrow in FIG. 4). In this case, the inert gas injected from each gas hole 31f bounces off the inner surface of the second sidewall 11b, thereby forming a gas flow F11 that flows along the inner surface of the third sidewall 11c and the inner surface of the first sidewall 11a.

Since the gas flow F11 flows along the third sidewall 11c having a rectifying effect toward the periphery of the substrate W, the inert gas may be efficiently introduced to the peripheral portion of the substrate W. As a result, the concentration of the processing gas may be selectively diluted while optimizing the amount of inert gas used.

Furthermore, when the arrangement of the gas holes 31f in the pipe wall (first pipe wall) is in an area between the half line L1 and the half line L2, a gas flow F12 toward the processing gas supply pipe 32a may be formed in addition to the gas flow F11. Since the gas flow F12 may dilute the processing gas in the processing gas injection area, the overall concentration of the processing gas in the surface of the substrate W may be diluted. Thus, the in-plane distribution of the film thickness may be adjusted gradually.

Here, when the gas injection direction from each gas hole 31f is set toward the half line L2 rather than the half line L1, the flow of the gas flow F11 may be more actively formed, thereby selectively diluting the concentration of the processing gas at the peripheral portion of the substrate W efficiently.

Furthermore, when the gas injection direction from each gas hole 31f is set toward the half line L1 rather than the half line L2, the flow of the gas flow F12 may be more actively formed, thereby enhancing the overall dilution effect of the concentration of the processing gas.

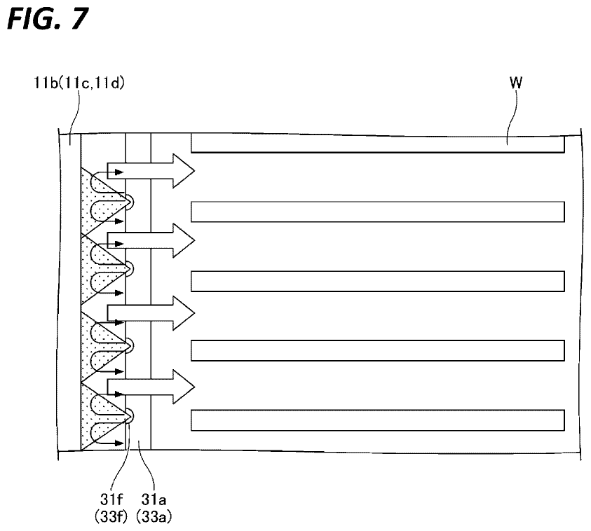

In addition, when each gas hole 31f injects the inert gas into the area between the half line L1 and the half line L2, the injected inert gas may also be diffused in the vertical direction as illustrated in FIG. 7. By forming an inert gas diffusion area in the vertical direction (inter-plane direction) on both sides where the processing gas is injected in this manner, the inter-plane uniformity may also be improved.

FIG. 4 also illustrates a case where each gas hole 31f is located at an intersection with the half line L1 in the pipe wall of the first inert gas supply pipe 31a (e.g., broken arrow in FIG. 4). In this case, as illustrated in FIG. 7, the inert gas injected from each gas hole 31f bounces off the inner surface of the second sidewall 11b, thereby improving the diffusibility in the vertical direction. Thus, the inter-plane uniformity of the processing is improved.

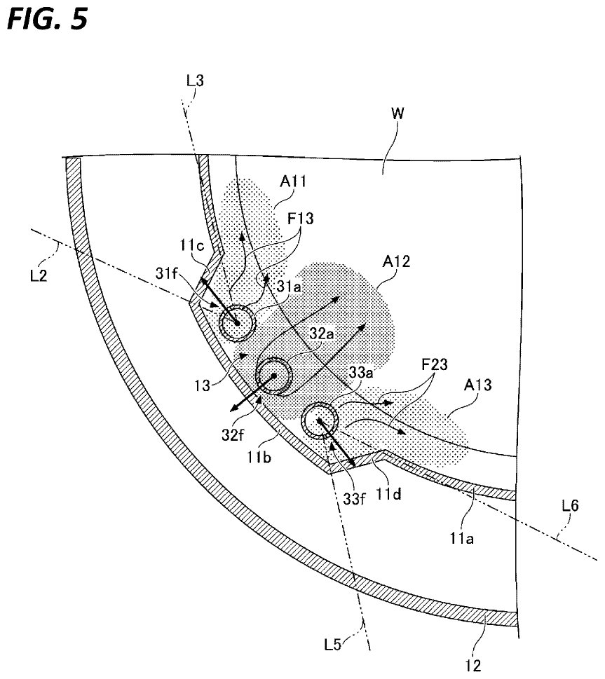

As illustrated in FIG. 5, each gas hole 31f may be located on the third sidewall 11c between the half line L2 and the half line L3 in the pipe wall of the first inert gas supply pipe 31a. In this case, the inert gas injected from each gas hole 31f bounces off the inner surface of the third sidewall 11c, thereby forming a gas flow F13 that flows along the inner surface of the third sidewall 11c and the inner surface of the first sidewall 11a. Meanwhile, a gas flow toward the processing gas supply pipe 32a is hardly formed. The gas flow F13 selectively dilutes the concentration of the processing gas at the peripheral portion of the substrate W. Thus, the in-plane distribution of the processing may be sharply adjusted. For this reason, it is particularly effective when it is desired to suppress the film thickness at the peripheral portion of the substrate W from becoming thick. Further, as illustrated in FIG. 7, the inert gas injected from each gas hole 31f bounces off the inner surface of the third sidewall 11b, thereby improving the diffusibility in the vertical direction. Thus, the inter-plane uniformity of the processing is improved.

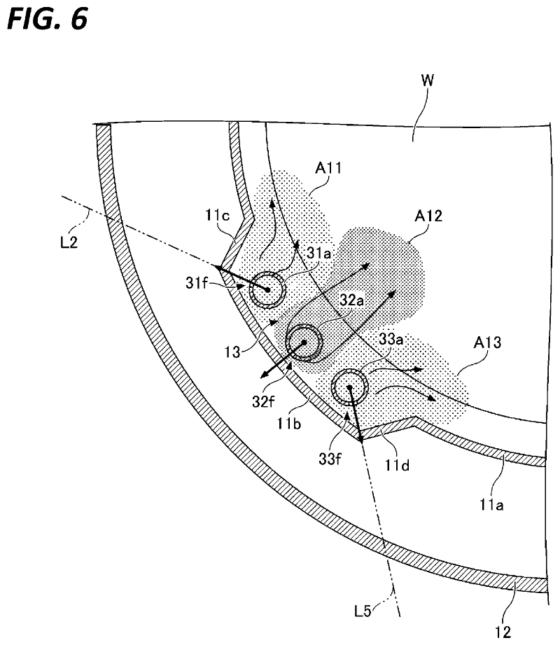

As illustrated in FIG. 6, each gas hole 31f may be located at an intersection with a half line L2 in the pipe wall of the first inert gas supply pipe 31a. In this case, an intermediate effect between the case illustrated in FIG. 4 and the case illustrated in FIG. 5 may be obtained.

As illustrated in FIG. 3, a half line extending from the center of the second inert gas supply pipe 33a toward the radial outward side of the substrate W is defined as a half line L4. A half line extending from the center of the second inert gas supply pipe 33a toward the boundary between the second sidewall 11b and the fourth sidewall 11d is defined as a half line L5. A half line extending from the center of the second inert gas supply pipe 33a toward the boundary between the first sidewall 11a and the fourth sidewall 11d is defined as a half line L6.

As illustrated in FIG. 4, each gas hole 31f may be located on the side of the second sidewall 11b (opposite to the side of the substrate W) between the half line L4 and the half line L5 in the pipe wall of the second inert gas supply pipe 33a (second pipe wall). That is, each gas hole 31f may be located in an area between the half line L4 and the half line L5 in the pipe wall of the second inert gas supply pipe 33a (second pipe wall). Thus, the second inert gas supply pipe 33a may inject inert gas toward the area between the half line L4 and the half line L5 of the second sidewall 11b (e.g., solid line arrow in FIG. 4). In this case, the inert gas injected from each gas hole 33f bounces off the inner surface of the second sidewall 11b, thereby forming a gas flow F21 that flows along the inner surface of the fourth sidewall 11d and the inner surface of the first sidewall 11a.

Since the gas flow F21 flows along the fourth sidewall 11d having a rectifying effect toward the periphery of the substrate W, the inert gas may be efficiently introduced to the peripheral portion of the substrate W. As a result, the concentration of the processing gas may be selectively diluted while optimizing the amount of inert gas used.

Furthermore, when the arrangement of the gas holes 33f in the pipe wall (second pipe wall) is in an area between the half line L4 and the half line L5, a gas flow F22 toward the processing gas supply pipe 32a may be formed in addition to the gas flow F21. Since the gas flow F22 may dilute the processing gas in the processing gas injection area, the overall concentration of the processing gas in the surface of the substrate W may be diluted. Thus, the in-plane distribution of the film thickness may be adjusted gradually.

Here, when the gas injection direction from each gas hole 33f is set toward the half line L5 rather than the half line L4, the flow of the gas flow F21 may be more actively formed, thereby selectively diluting the concentration of the processing gas at the peripheral portion of the substrate W efficiently.

Furthermore, when the gas injection direction from each gas hole 33f is set toward the half line L4 rather than the half line L5, the flow of the gas flow F22 may be more actively formed, thereby enhancing the overall dilution effect of the concentration of the processing gas.

In addition, when each gas hole 33f injects the inert gas into the area between the half line L1 and the half line L2, the injected inert gas may also be diffused in the vertical direction as illustrated in FIG. 7. By forming an inert gas diffusion area in the vertical direction (inter-plane direction) on both sides where the processing gas is injected in this manner, the inter-plane uniformity may also be improved.

FIG. 4 also illustrates a case where each gas hole 33f is located at an intersection with the half line L4 in the pipe wall of the second inert gas supply pipe 33a (e.g., broken arrow in FIG. 4). In this case, as illustrated in FIG. 7, the inert gas injected from each gas hole 33f bounces off the inner surface of the second sidewall 11b, thereby improving the diffusibility in the vertical direction. Thus, the inter-plane uniformity of the processing is improved.

As illustrated in FIG. 5, each gas hole 31f may be located on the fourth sidewall 11d between the half line L5 and the half line L6 in the pipe wall of the second inert gas supply pipe 33a. In this case, the inert gas injected from each gas hole 33f bounces off the inner surface of the fourth sidewall 11d, thereby forming a gas flow F23 that flows along the inner surface of the fourth sidewall 11d and the inner surface of the first sidewall 11a. Meanwhile, a gas flow toward the processing gas supply pipe 32a is hardly formed. The gas flow F23 selectively dilutes the concentration of the processing gas at the peripheral portion of the substrate W. Thus, the in-plane distribution of the processing may be sharply adjusted. For this reason, it is particularly effective when it is desired to suppress the film thickness at the peripheral portion of the substrate W from becoming thick. As illustrated in FIG. 7, the inert gas injected from each gas hole 33f bounces off the inner surface of the fourth sidewall 11d, thereby improving the diffusibility in the vertical direction. Thus, the inter-plane uniformity of the processing is improved.

As illustrated in FIG. 6, each gas hole 33f may be located at an intersection with a half line L5 in the pipe wall of the second inert gas supply pipe 33a. In this case, an intermediate effect between the case illustrated in FIG. 4 and the case illustrated in FIG. 5 may be obtained.

In FIGS. 4 to 6, when the processing gas is injected from each gas hole 32f toward the inner surface of the second sidewall 11b, the diffusion range of the gas immediately after being injected from each gas hole 31f, 32f, 33f is illustrated as areas A11, A12, A13, respectively.

The gas supply unit 30 may mix a plurality of types of gases and inject the mixed gas from one supply pipe. The gas supply pipes (the first inert gas supply pipe 31a, the processing gas supply pipe 32a, and the second inert gas supply pipe 33a) may have different shapes and arrangements. For example, one or both of the first inert gas supply pipe 31a and the second inert gas supply pipe 33a may be folded gas supply pipes that are bent in an L-shape at the bottom and folded back in a U-shape at the top to extend downward. For example, the processing gas supply pipe 32a may be a folded gas supply pipe.

The gas supply unit 30 may further include another gas supply pipe in addition to the first inert gas supply pipe 31a, the processing gas supply pipe 32a, and the second inert gas supply pipe 33a. For example, a plurality of processing gas supply pipes may be provided between the first inert gas supply pipe 31a and the second inert gas supply pipe 33a. The plurality of processing gas supply pipes may be gas supply pipes that supply the same processing gas, or may be gas supply pipes that supply different processing gases. For example, one or more inert gas supply pipes may be provided between the first inert gas supply pipe 31a and the processing gas supply pipe 32a. For example, one or more inert gas supply pipes may be provided between the processing gas supply pipe 32a and the second inert gas supply pipe 33a.

As indicated by the arrow in FIG. 2, the exhaust unit 40 exhausts gas that is discharged from the inner pipe 11 through the exhaust slits 15 and reaches an exhaust port 41 through a space P1 between the inner pipe 11 and the outer pipe 12. The exhaust port 41 is formed on an upper sidewall of the manifold 17 and above the support unit 20. An exhaust passage 42 is connected to the exhaust port 41. A pressure adjustment valve 43 and a vacuum pump 44 are sequentially provided in the exhaust passage 42 so that the inside of the processing container 10 may be exhausted.

The heating unit 50 is provided around the outer pipe 12. The heating unit 50 is provided on, for example, abase plate 28. The heating unit 50 has a cylindrical shape to cover the outer pipe 12. The heating unit 50 includes, for example, a heater, and heats each substrate W in the processing container 10.

The control unit 90 controls the operation of each part of the substrate processing apparatus 1 to process a plurality of substrates W accommodated in the processing container 10 at one time. The control unit 90 may be, for example, a computer. A computer program for controlling the operation of each part of the substrate processing apparatus 1 is stored in a storage medium. The storage medium may be, for example, a flexible disk, a compact disk, a hard disk, a flash memory, or a DVD.

Next, a description will be made on a substrate processing method performed using the substrate processing apparatus 1 according to the embodiment. The substrate processing method according to the embodiment is performed by a control unit 90 controlling the operation of each unit of the substrate processing apparatus 1.

First, the boat 16 holding a plurality of substrates W is moved up from below into the processing container 10, the temperature of which has been adjusted in advance, and the inside of the processing container 10 is sealed by closing the opening at the bottom end of the processing container 10 with the lid 21. Next, the inside of the processing container 10 is evacuated by the exhaust unit 40 to maintain a process pressure, and the substrate temperature is raised and maintained at a process temperature by the heating unit 50. Then, the boat 16 is rotated by the rotation of the rotation shaft 24.

Next, the control unit 90 injects the processing gas from the processing gas supply pipe 32a into the processing container 10, while injecting the inert gas from the first inert gas supply pipe 31a and the second inert gas supply pipe 33a toward the inner surface of the second sidewall 11b, the third sidewall 11c, or the fourth sidewall 11d. Thus, each substrate W is processed at once. At this time, the inert gas flows along the third sidewall 11c or the fourth sidewall 11d, so that the inert gas is efficiently supplied to the gap between the outer end of the substrate W and the inner surface of the first sidewall 11a. Therefore, the pressure in the gap between the outer edge of the substrate W and the inner surface of the first sidewall 11a may be made relatively high by using a small flow rate of the inert gas, so that the processing gas may be suppressed from flowing into the gap. As a result, the amount of inert gas used may be reduced, thereby reducing the environmental load, while promoting the supply of the processing gas to the center of each substrate W and reducing the difference in the amount of processing gas supplied between the peripheral portion and the center portion of each substrate W.

The flow rate of the inert gas injected from the first inert gas supply pipe 31a may be lower than, for example, the flow rate of the processing gas injected from the processing gas supply pipe 32a. The flow rate of the inert gas injected from the second inert gas supply pipe 33a may be lower than, for example, the flow rate of the processing gas injected from the processing gas supply pipe 32a. That is, in the substrate processing apparatus 1 according to the present embodiment, the flow rates of the inert gas injected from the first inert gas supply pipe 31a and the second inert gas supply pipe 33a may be set lower than the flow rate of the processing gas, due to the inert gas rectifying effect of the third sidewall 11c or the fourth sidewall 11d.

Next, after the pressure inside the processing container 10 is increased to atmospheric pressure, and the temperature inside the processing container 10 is decreased to an unloading temperature, the boat 16 holding the plurality of processed substrates W is then unloaded from the processing container 10.

### Second Embodiment

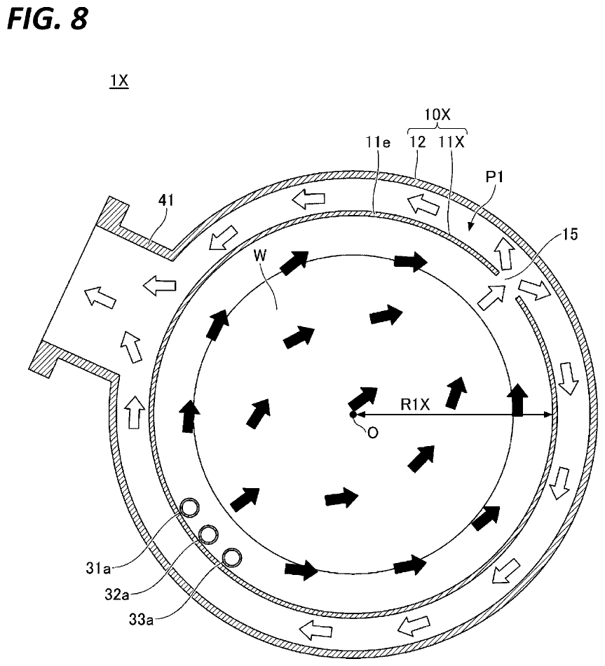

A substrate processing apparatus 1X according to a second embodiment will be described with reference to FIGS. 8 to 12. The substrate processing apparatus 1X differs from the substrate processing apparatus 1 in that the nozzle accommodating section 13 is not provided. Other configurations may be similar to those of the substrate processing apparatus 1. The following description will focus on the differences from the substrate processing apparatus 1.

As illustrated in FIG. 8, the substrate processing apparatus 1X includes a processing container 10X having an inner pipe 11X and an outer pipe 12, instead of the processing container 10. The inner pipe 11X has a fifth sidewall 11e.

The fifth sidewall 11e extends along the circumferential direction of the substrates W. The fifth sidewall 11e has a cylindrical shape. A rectangular exhaust slit 15 is formed along a longitudinal direction (vertical direction) of the fifth sidewall 11e in a portion of the circumferential direction. A radius R1X of the fifth sidewall 11e is larger than the radius R1 of the arc of the first sidewall 11a of the substrate processing apparatus 1. Thus, each gas supply pipe (the first inert gas supply pipe 31a, the processing gas supply pipe 32a, and the second inert gas supply pipe 33a) may be disposed between the outer end of the substrate W and the inner surface of the fifth sidewall 11e.

The first inert gas supply pipe 31a and the second inert gas supply pipe 33a are each configured to inject the inert gas toward the inner surface of the fifth sidewall 11e. In this case, the inert gas bounces off the inner surface of the fifth sidewall 11e, so that the inert gas is efficiently supplied to the gap between the outer end of the substrate W and the inner surface of the fifth sidewall 11e. Therefore, the pressure in the gap between the outer edge of the substrate W and the inner surface of the fifth sidewall 11e may be made relatively high by using a small flow rate of the inert gas, so that the processing gas may be suppressed from flowing into the gap. As a result, the amount of inert gas used may be reduced, thereby reducing the environmental load, while promoting the supply of the processing gas to the center of each substrate W and reducing the difference in the amount of processing gas supplied between the peripheral portion and the center portion of each substrate W.

The inert gas injected from each gas hole 31f and each gas hole 33f bounces off the inner surface of the fifth sidewall 11e, thereby forming a gas flow along the inner surface of the fifth sidewall 11e away from the processing gas supply pipe 32a and a gas flow toward the processing gas supply pipe 32a. The gas flow along the inner surface of the fifth sidewall 11e away from the processing gas supply pipe 32a selectively dilutes the concentration of the processing gas at the peripheral portion of the substrate W. The gas flow toward the processing gas supply pipe 32a dilutes the overall concentration of the processing gas in the plane of the substrate W.

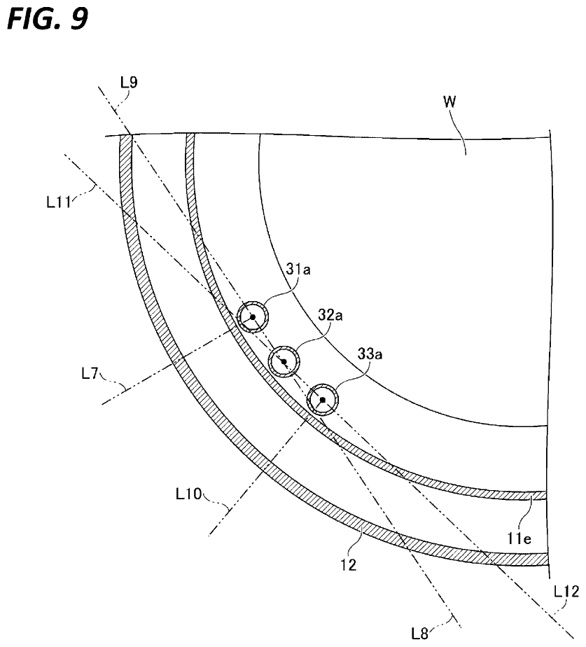

As illustrated in FIG. 9, a half line extending from the center of the first inert gas supply pipe 31a toward the radial outward side of the substrate W is defined as a half line L7. A half line extending from the center of the first inert gas supply pipe 31a toward the center of the processing gas supply pipe 32a is defined as a half line L8. A half line extending from the center of the first inert gas supply pipe 31a toward a side perpendicular to the half line L7 and opposite to the processing gas supply pipe 32a is defined as a half line L9.

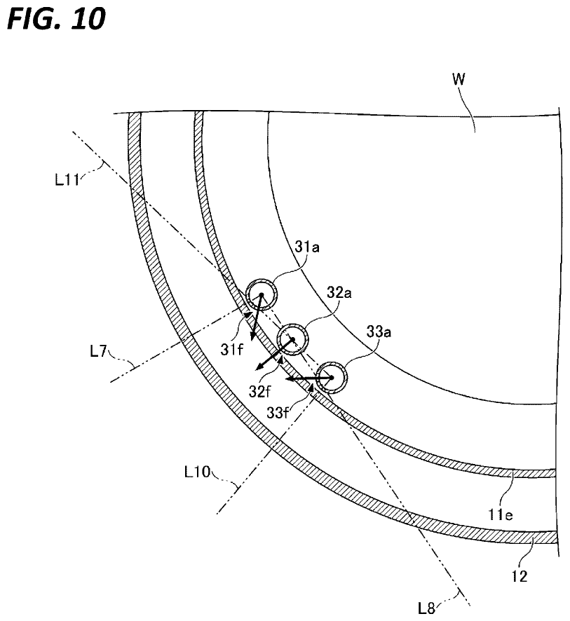

As illustrated in FIG. 10, each gas hole 31f may be located on the side of the fifth sidewall 11e (opposite to the side of the substrate W) between the half line L7 and the half line L8 in the pipe wall of the first inert gas supply pipe 31a. That is, each gas hole 31f may be located in an area between the half line L7 and the half line L8 in the pipe wall of the first inert gas supply pipe 31a (first pipe wall). In this case, the gas flow toward the processing gas supply pipe 32a becomes larger than the gas flow away from the processing gas supply pipe 32a along the inner surface of the fifth sidewall 11e. Thus, the in-plane distribution of the processing may be gently adjusted.

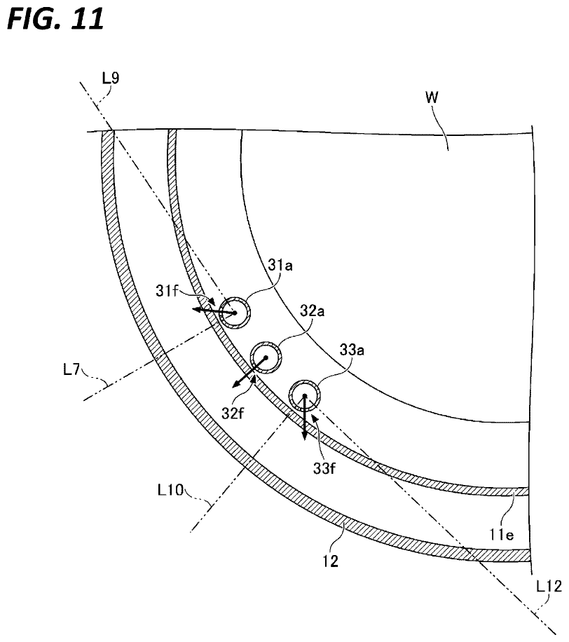

Further, as illustrated in FIG. 11, each gas hole 31f may be located on the side of the fifth sidewall 11e (opposite to the side of the substrate W) between the half line L7 and the half line L9 in the pipe wall of the first inert gas supply pipe 31a. That is, each gas hole 31f may be located in an area between the half line L7 and the half line L9 in the pipe wall of the first inert gas supply pipe 31a (first pipe wall). In this case, the gas flow away from the processing gas supply pipe 32a along the inner surface of the fifth sidewall 11e becomes larger than the gas flow toward the processing gas supply pipe 32a. Thus, the in-plane distribution of the processing may be sharply adjusted. For this reason, it is particularly effective when it is desired to suppress the film thickness at the peripheral portion of the substrate W from becoming thick.

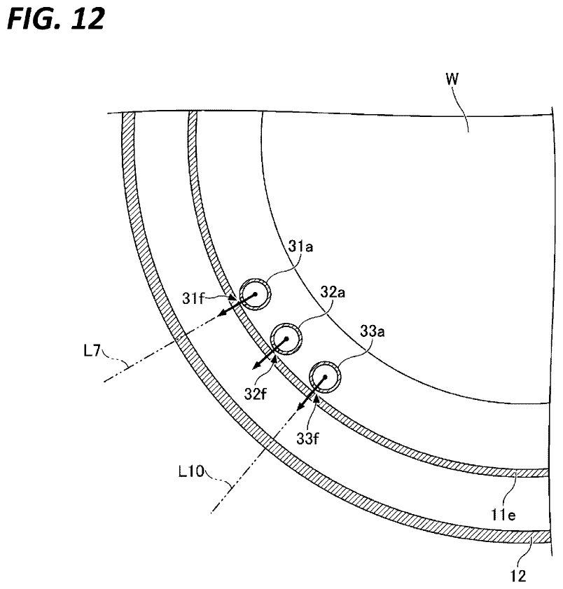

Further, as illustrated in FIG. 12, each gas hole 31f may be located at an intersection with a half line L7 in the pipe wall of the first inert gas supply pipe 31a. In this case, the gas flow away from the processing gas supply pipe 32a along the inner surface of the fifth sidewall 11e and the gas flow toward the processing gas supply pipe 32a are approximately equal. Therefore, an intermediate effect between the case illustrated in FIG. 10 and the case illustrated in FIG. 11 may be obtained.

As illustrated in FIG. 9, a half line extending from the center of the second inert gas supply pipe 33a toward the radial outward side of the substrate W is defined as a half line L10. A half line extending from the center of the second inert gas supply pipe 33a toward the center of the processing gas supply pipe 32a is defined as a half line L11. A half line extending from the center of the second inert gas supply pipe 33a toward a side perpendicular to the half line L10 and opposite to the processing gas supply pipe 32a is defined as a half line L12.

As illustrated in FIG. 10, each gas hole 31f may be located on the side of the fifth sidewall 11e (opposite to the side of the substrate W) between the half line L10 and the half line L11 in the pipe wall of the second inert gas supply pipe 33a. That is, each gas hole 31f may be located in an area between the half line L10 and the half line L11 in the pipe wall of the second inert gas supply pipe 33a (second pipe wall). In this case, the gas flow toward the processing gas supply pipe 32a becomes larger than the gas flow away from the processing gas supply pipe 32a along the inner surface of the fifth sidewall 11e. Thus, the in-plane distribution of the process may be gently adjusted.

Further, as illustrated in FIG. 11, each gas hole 31f may be located on the side of the fifth sidewall 11e (opposite to the side of the substrate W) between the half line L10 and the half line L12 in the pipe wall of the second inert gas supply pipe 33a. That is, each gas hole 31f may be located in an area between the half line L10 and the half line L12 in the pipe wall of the second inert gas supply pipe 33a (second pipe wall). In this case, the gas flow away from the processing gas supply pipe 32a along the inner surface of the fifth sidewall 11e becomes larger than the gas flow toward the processing gas supply pipe 32a. Thus, the in-plane distribution of the processing may be sharply adjusted. For this reason, it is particularly effective when it is desired to suppress the film thickness at the peripheral portion of the substrate W from becoming thick.

Further, as illustrated in FIG. 12, each gas hole 31f may be located at an intersection with a half line L10 in the pipe wall of the second inert gas supply pipe 33a. In this case, the gas flow away from the processing gas supply pipe 32a along the inner surface of the fifth sidewall 11e and the gas flow toward the processing gas supply pipe 32a are approximately equal. Therefore, an intermediate effect between the case illustrated in FIG. 10 and the case illustrated in FIG. 11 may be obtained.

FIGS. 10 to 12 illustrate an example in which the processing gas is injected from each gas hole 32f toward the inner surface of the fifth sidewall 11e. However, the present disclosure is not limited to this example, and the processing gas supply pipe 32a may be configured to inject the processing gas, for example, directly toward the center O of the substrate W without injecting the processing gas toward the fifth sidewall 11e.

According to the present disclosure, the uniformity of processing is improved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing container configured to accommodate a plurality of substrates arranged in multiple tiers;
a processing gas supply pipe extending along an arrangement direction of the plurality of substrates and configured to supply a processing gas into the processing container; and
a pair of inert gas supply pipes provided at positions sandwiching the processing gas supply pipe therebetween along a circumferential direction of the plurality of substrates while extending along the arrangement direction, and configured to supply an inert gas into the processing container,
wherein the pair of inert gas supply pipes are configured to inject the inert gas toward an inner surface of a sidewall of the processing container, so that the inner surface forms a flow of the inert gas in the circumferential direction of the plurality of substrates.

2. The substrate processing apparatus according to claim 1, wherein the processing gas supply pipe is configured to inject the processing gas toward the inner surface of the sidewall.

3. The substrate processing apparatus according to claim 1, wherein the sidewalls include:
a first sidewall extending along the circumferential direction,
a second sidewall located on a radial outward side of the plurality of substrates from the first sidewall and extending along the circumferential direction at a position different from the first sidewall in the circumferential direction,
a third sidewall connected to one end of the first sidewall and one end of the second sidewall, and
a fourth sidewall connected to a remaining end of the first sidewall and a remaining end of the second sidewall, and
the processing gas supply pipe and the pair of inert gas supply pipes are provided in an area surrounded by the second sidewall, the third sidewall, and the fourth sidewall.

4. The substrate processing apparatus according to claim 3, wherein an angle between the second sidewall and the third sidewall and an angle between the second sidewall and the fourth sidewall are obtuse angles.

5. The substrate processing apparatus according to claim 3, wherein the pair of inert gas supply pipes include:
a first inert gas supply pipe located closer to the third sidewall than the processing gas supply pipe and having a first pipe wall with a plurality of first gas holes formed along the arrangement direction, and
a second inert gas supply pipe located closer to the fourth sidewall than the processing gas supply pipe and having a second pipe wall with a plurality of second gas holes formed along the arrangement direction,
the first inert gas supply pipe is configured to inject the inert gas from the plurality of first gas holes toward the second sidewall or the third sidewall, and
the second inert gas supply pipe is configured to inject the inert gas from the plurality of second gas holes toward the second sidewall or the fourth sidewall.

6. The substrate processing apparatus according to claim 5, wherein in a cross section perpendicular to the arrangement direction, when a half line extending from a center of the first inert gas supply pipe toward the radial outward side is defined as the first half line, and a half line extending from the center of the first inert gas supply pipe toward a boundary between the second sidewall and the third sidewall is defined as a second half line, the plurality of first gas holes are located in an area of the first pipe that is sandwiched between the first half line and the second half line.

7. The substrate processing apparatus according to claim 5, wherein in a cross section perpendicular to the arrangement direction, when a half line extending from a center of the first inert gas supply pipe toward the radial outward side is defined as a first half line, the plurality of first gas holes are located at intersections of the first pipe wall with the first half line.

8. The substrate processing apparatus according to claim 5, wherein in a cross section perpendicular to the arrangement direction, when a half line extending from a center of the first inert gas supply pipe toward a boundary between the second sidewall and the third sidewall is defined as a second half line, the plurality of first gas holes are located at intersections of the first pipe wall with the second half line.

9. The substrate processing apparatus according to claim 5, wherein in a cross section perpendicular to the arrangement direction, when a half line extending from a center of the first inert gas supply pipe toward a boundary between the second sidewall and the third sidewall is defined as a second half line, and a half line extending from the center of the first inert gas supply pipe toward a boundary between the first sidewall and the third sidewall is defined as a third half line, the plurality of first gas holes are located in an area of the first pipe wall that is sandwiched between the second half line and the third half line.

10. The substrate processing apparatus according to claim 5, wherein in a cross section perpendicular to the arrangement direction, when a half line extending from a center of the second inert gas supply pipe toward the radial outward side is defined as a fourth half line, and a half line extending from the center of the second inert gas supply pipe toward a boundary between the second sidewall and the fourth sidewall is defined as a fifth half line, the plurality of second gas holes are located in an area of the second pipe wall that is sandwiched between the fourth half line and the fifth half line.

11. The substrate processing apparatus according to claim 5, wherein in a cross section perpendicular to the arrangement direction, when a half line extending from a center of the second inert gas supply pipe toward the radial outward side is defined as a fourth half line, the plurality of second gas holes are located at intersections of the second pipe wall with the fourth half line.

12. The substrate processing apparatus according to claim 5, wherein in a cross section perpendicular to the arrangement direction, when a half line extending from a center of the second inert gas supply pipe toward a boundary between the second sidewall and the fourth sidewall is defined as a fifth half line, the plurality of second gas holes are located at intersections of the second pipe wall with the fifth half line.

13. The substrate processing apparatus according to claim 5, wherein in a cross section perpendicular to the arrangement direction, when a half line extending from a center of the second inert gas supply pipe toward a boundary between the second sidewall and the fourth sidewall is defined as a fifth half line, and a half line extending from the center of the second inert gas supply pipe toward a boundary between the first sidewall and the fourth sidewall is defined as a sixth half line, the plurality of second gas holes are located in an area of the second pipe wall that is sandwiched between the fifth half line and the sixth half line.

14. A substrate processing method comprising:
providing a substrate processing apparatus including:
a processing container configured to accommodate a plurality of substrates arranged in multiple tiers;
a processing gas supply pipe extending along an arrangement direction of the plurality of substrates and configured to supply a processing gas into the processing container; and
a pair of inert gas supply pipes provided at positions sandwiching the processing gas supply pipe therebetween along a circumferential direction of the plurality of substrates while extending along the arrangement direction, and configured to supply an inert gas into the processing container; and
injecting the inert gas from the pair of inert gas supply pipes toward an inner surface of a sidewall of the processing container while injecting the processing gas into from the processing gas supply pipe into the processing container.

15. The substrate processing method according to claim 14, wherein a flow rate of the inert gas injected from each of the pair of inert gas supply pipes is less than a flow rate of the processing gas injected from the processing gas supply pipe.
